(19) United States
(12) Patent Application Publication
(10) Pub. No.: US 2019/0182994 A1
(43) Pub. Date: Jun. 13, 2019

(54) HEAD UP DISPLAY COOLING

(71) Applicant: Panasonic Automotive Systems Company of America, Division of Panasonic Corporation of North America, Peachtree City, GA (US)

(72) Inventors: Patrick O'CONNELL, Novi, MI (US); Edo OMANOVIC, Livonia, MI (US)

(73) Assignee: Panasonic Automotive Systems Company of America, Division of Panasonic Corporation of North America

(21) Appl. No.: 16/137,966

(22) Filed: Sep. 21, 2018

Related U.S. Application Data
(60) Provisional application No. 62/598,157, filed on Dec. 13, 2017.

(51) Int. Cl. H05K 7/20; B60H 1/00

(52) U.S. Cl. CPC H05K 7/20963; H05K 7/20209; B60K 35/00; B60H 1/00271; B60H 1/00678; H05K 7/20127

(57) ABSTRACT

Examples of the present disclosure relate to a device, method, and system for cooling a Head Up Display (HUD). A vehicle may include a HUD which generates heat and as such may need cooling. In an example, the present techniques relate to a HUD module to emit light with a Picture Generation Unit (PGU). The specification may include a heatsink attached to the HUD module to draw heat from the PGU through conduction and dissipate heat through convection. The techniques may further include a Heating, Ventilation, and Air Conditioning (HVAC) duct with an outlet to direct airflow from the HVAC duct towards the heatsink.

### CROSS-REFERENCE TO RELATED APPLICATIONS

This application claims the benefit of U.S. Provisional Application No. 62/598,157, filed on Dec. 13, 2017, which the disclosure of which is hereby incorporated by reference in its entirety for all purposes.

### FIELD OF THE INVENTION

The present disclosure generally relates to a method, system, and device for cooling a Head Up Display (HUD) in a vehicle. More specifically, the present disclosure relates to cooling a HUD with an attached heatsink and an outlet in a nearby Heating and Ventilation Air Conditioning duct to direct air towards and through the heatsink.

### BACKGROUND

This section is intended to introduce the reader to various aspects of art, which may be related to various aspects of the present disclosure, which are described and/or claimed below. This discussion is believed to be helpful in providing the reader with background information to facilitate a better understanding of the various aspects of the present disclosure. Accordingly, it can be understood that these statements are to be read in this light, and not as admissions of prior art.

Vehicles, such as automobiles may utilize a Head Up Display (HUD) to alert a driver or passenger of relevant information, navigational directions, warnings, entertainment, or other light based features. The generation of light can include generation of heat energy.

### SUMMARY

This specification generally discloses a HUD cooling system, method and device. In an example, the vehicle head up display cooling system can include a head up display module to emit light with a Picture Generation Unit (PGU). The system may also include a heatsink attached to the HUD module to draw heat from the PGU through conduction and dissipate heat through convection. The system includes a Heating, Ventilation, and Air Conditioning (HVAC) duct with an outlet to direct airflow from the HVAC duct towards the heatsink.

An example method for cooling a HUD in a vehicle, includes emitting light with a PGU of a HUD module. The method may also draw heat from the PGU through conduction by contact of a heatsink to the PGU, where the heatsink is attached to the HUD module and dissipates heat through convection. The example method may also direct airflow from an HVAC duct towards the heatsink, the airflow directed by an outlet on the HVAC duct.

A device for HUD cooling includes a head up display HUD module to emit light with a PGU. The device may include a heatsink attached to the HUD module to draw heat from the PGU through conduction and dissipate heat through convection. The device may include a HVAC duct with an outlet to direct airflow from the HVAC duct towards the heatsink.

### BRIEF DESCRIPTION OF THE DRAWINGS

The above-mentioned and other features and advantages of the present disclosure, and the manner of attaining them, may become apparent and be better understood by reference to the following description of one example of the disclosure in conjunction with the accompanying drawings, wherein:

FIG. 1 is a schematic of an example head up display cooling system;

FIG. 2 is a drawing of airflow through an HVAC outlet and heatsink;

FIG. 3 is a schematic of an example HUD cooling device with a temperature sensor and valve on the HVAC outlet;

FIG. 4 is a process flow diagram of an example method for cooling a HUD; and

FIG. 5 is a drawing of an example computer-readable medium storing instructions, that when executed on a processor cools a HUD through control of an HVAC outlet valve.

Correlating reference characters indicate correlating parts throughout the several views. The exemplifications set out herein illustrate examples of the disclosure, in one form, and such exemplifications are not to be construed as limiting in any manner the scope of the disclosure.

### DETAILED DESCRIPTION OF EXAMPLES

In an effort to provide a concise description of these examples, not all features of an actual implementation are described in the specification. It can be appreciated that in the development of any such actual implementation, as in any engineering or design project, numerous implementation-specific decisions may be made to achieve the developers' specific goals, such as compliance with system-related and business-related constraints, which may vary from one implementation to another. Moreover, it can be appreciated that such a development effort might be complex and time consuming, and is a routine undertaking of design, fabrication, and manufacture for those of ordinary skill having the benefit of this disclosure.

The present disclosure describes cooling for Head Up Displays (HUDs) through increased airflow within the instrument panel. HUDs include light emitting components that generate heat that is trapped within the enclosed space of the dashboard of a vehicle. The more heat is generated the light emitting sources of the HUD, the more heat that builds up. Rather than increase the size of a heatsink in an already crowded instrument panel area, the present disclosure relates to making use of a nearby Heating, Ventilation and Air Conditioning (HVAC) duct for airflow. By adding an outlet to the HVAC duct, the HUD can increase airflow and heat dissipation through the heatsink. By increasing airflow, the size of the heatsink can be decreased while still dissipating the same amount of heat or more. The addition of an outlet on the HVAC duct means that no moving parts such as fans are needed to generate air movement. The present disclosure relates to a solution that increases heat dissipation while reducing the amount of space occupied by the heatsink in the instrument panel.

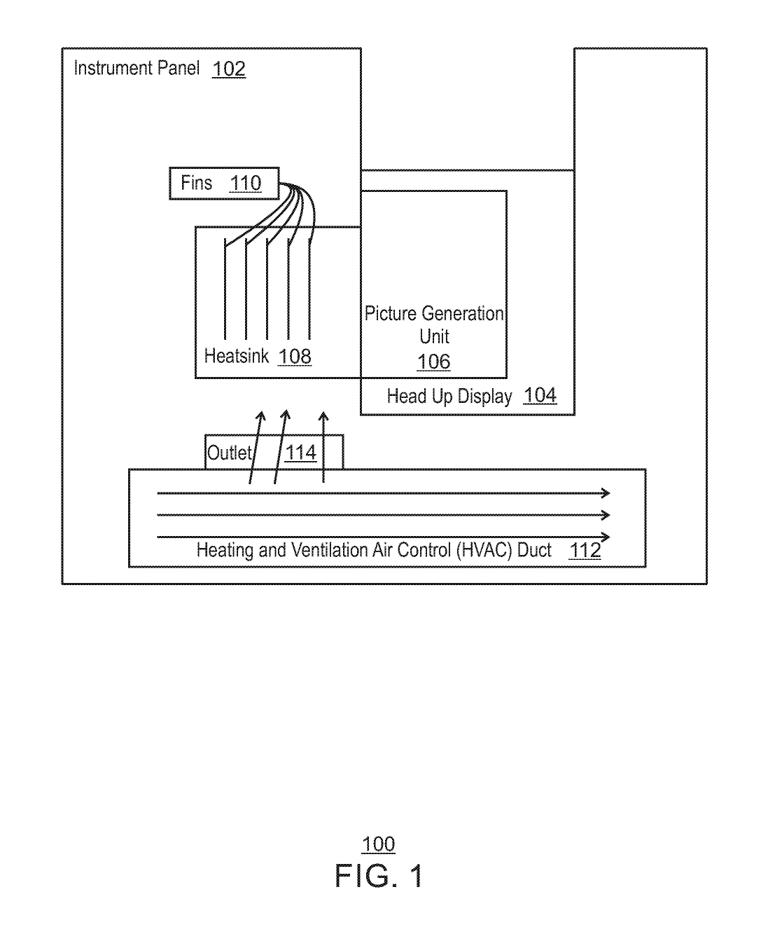

FIG. 1 is a schematic of an example head up display cooling system 100. Directional arrows located in this figure indicate a general airflow or movement of air unless the arrow is pointing directly to an object such as the fins of the heatsink.

The HUD cooling system 100 is housed within an instrument panel 102 of a vehicle. The instrument panel can include displays, electronics, ventilation, and other user interfaces with both the operation of the vehicle and with electronic features used for navigation, temperature control, entertainment and similar activities. The instrument panel may include a Head Up Display (HUD) 104. The HUD 104 may include alerts, warnings, speeds, temperature gauges, odometers, estimated times of arrival, a back-up camera display, and other pictures, numbers, and information about the vehicle, location of the car, user information, and the like. The information displayed on the HUD 104 can be displayed with a Picture Generation Unit (PGU) 106 which can be a light display based on a number of technologies. In an example, the PGU 106 can include a Liquid Crystal Display (LCD), an LCD display with Light Emitting Diodes (LEDs) behind the LCD display to increase visibility, a Digital Kight Processing (DLP) display, and other light emitting displays.

To improve heat dissipation, the HUD 104 can include a heatsink 108 that is attached to the HUD 104 or the PGU 106 itself. The heatsink 108 can be a passive heat exchanger that transfers the heat from the PGU 106 to the air within the instrument panel 102. In an example, the heatsink 108 may be a molded or shaped material, metal, aluminum alloy, copper, or other materials with a thermal conductivity utility. The heatsink may be molded or shaped to have a number of protrusions on one end called fins 110. The fins 110 in FIG. 1 are shown from above and are shown to be parallel to each other although other configurations and shapes are possible. For example, the fins could be curved. The fins may be elongated protrusions that increase the surface area of the heatsink 108 to the surrounding air for increase rate of heat transfer from the PGU 106 to the air within the instrument panel 102.

Due to the heat generated by the light emitters of the PGU 106, the PGU 106 can be a large source of heat within the HUD 104 and the instrument panel 102. In a closed or semi-closed space like the instrument panel 102, heat generation can lead to degrading the quality and function of components over time. To increase heat dissipation without increasing the size of the heatsink 108, the HUD cooling system 100 includes a Heating and Ventilation Air Conditioning (HVAC) duct 112 with an outlet 114 to direct airflow towards the heatsink 108. The HVAC duct 112 in FIG. 1 is shown as s discrete unit, however, in practice it may be tubing, piping, or a channel for air moving through the vehicle to heat or cool the interior for drivers and passengers. Whether the air in the HVAC duct is heated or cooled for human comfort, the temperature range of the air moving in the HVAC duct 112 is likely to be cooler than the PGU 106 and heatsink 108 and accordingly, the air moving over across the fins 110 can pull heat away from the heatsink 108, PGU 106, and HUD 104.

To direct the airflow from the HVAC duct to across and through the fins 110 of the heatsink 108, the HVAC duct 112 can include an outlet 114. The outlet 114 can be positioned such that it creates an opening for air movement to pass in a direction parallel or approximately parallel to the fins 110 of the heatsink 108. The movement of air through the fins increases the heat dissipation and speed of heat transfer as the moving air more quickly carries away hot air and exposes the fins to newer, likely colder air. The outlet 114 can be an opening made in the HVAC duct 112 at a determined location. In an example, the outlet 114 may also be a physical attachment that includes directional opening to steer the air more specifically towards the heatsink 108. In an example, the outlet can include an airflow collecting protrusion into tie HVAC duct 112 that effectively redirects moving air from its usual path out from the HVAC duct towards the heatsink 108. Due to the airflow increasing the heat dispersion rate, the heatsink may be smaller than if the air in the instrument panel 102 were stagnant. Further, the use of an outlet to redirect some of the air from an HVAC duct creates moving air across the heatsink 108 without using moving parts, such as a fan, to generate airflow inside the instrument panel 102.

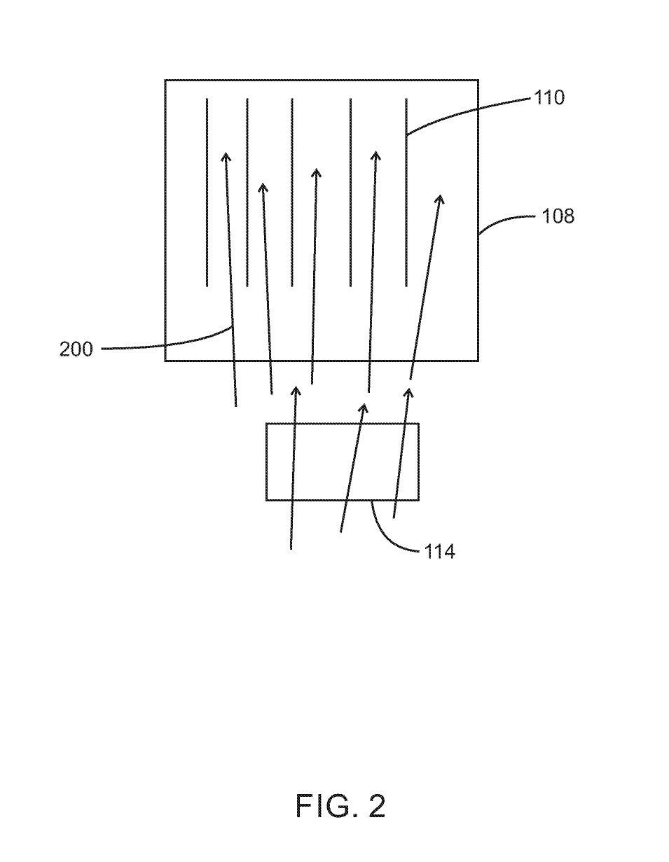

FIG. 2 is a drawing of airflow 200 through an HVAC outlet 114 and heatsink 108. Like numbered items are as disclosed above with respect to FIG. 1. As above, the arrows shown represent one possible direction of airflow.

FIG. 2 shows a zoomed-in perspective of the heatsink 108 to show how the outlet 114 may direct airflow 200 to move through the fins 110. The position of the airflow 200 may be determined by the location of the outlet 114 as well as the angle of the outlet 114. In an example, the position of the outlet 114 may steer the airflow 200 both parallel to the direction of the fins 110. In an example, the outlet may also be located so that the airflow 200 passes through the channels between the fins 110. While other shapes and configurations of heatsinks 108 and fins 110 is possible, the straight and parallel configuration exposes an increased surface area to the air and creates a path for air to travel both against the fins 110 and the away from the heatsink 108.

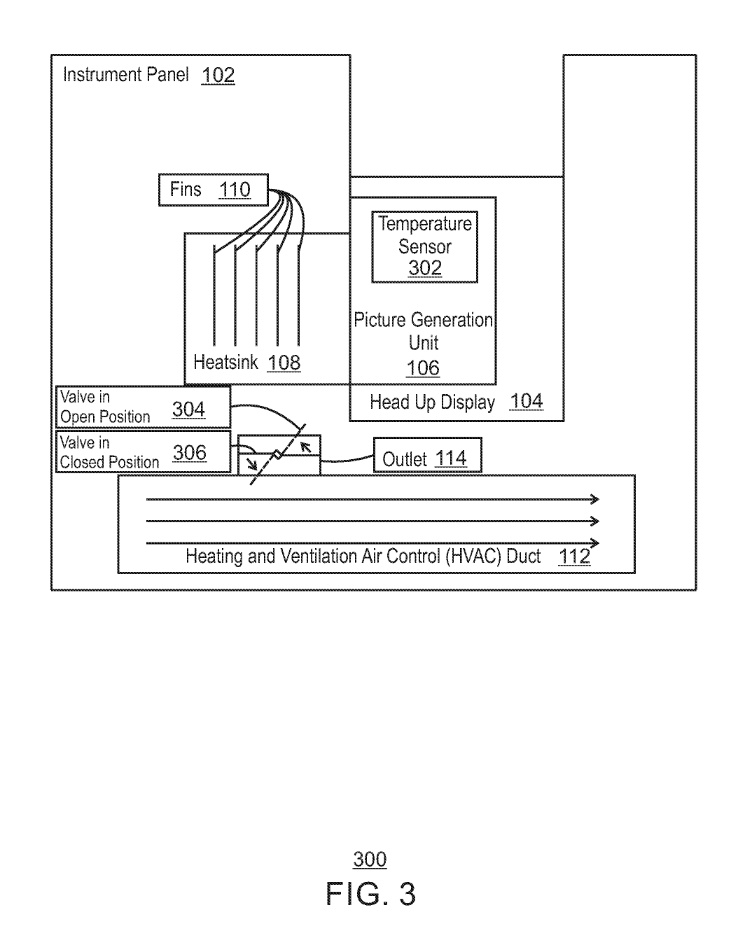

FIG. 3 is a schematic of an example HUD cooling device 300 with a temperature sensor and valve on the HVAC outlet. Like numbered items are as disclosed with respect to Fig, 1. Directional arrows in this figure indicate a general airflow or movement of air unless the arrow is pointing directly to an object such as the tins of the heatsink. Further, although no arrows are here shown for airflow out of the outlet 114, this is for convenience to allow other elements of this figure to be seen more clearly. As with the other figures, these drawings are simplified versions and omit many components, connections, or elements such as electrical wiring, display screens, user interfaces, and structural details that may distract from the disclosed techniques.

In FIG. 3, the PGU 106 includes a temperature sensor 302. The temperature sensor 302 can be analog or digital. In an example, the temperature sensor 302 can be a thermistor or other temperature sensing hardware. In an example, the PGU 106 may include the temperature sensor 302 as well as a subcomponent of the PGU 106, such as an LED or display of the PGU 106. The temperature sensor 302 may also be included and attached to the heatsink 108 itself rather than the PGU 106 as shown in the figure. The PGU 106 or HUD 104 may avoid damage and degradation by keeping their temperature at a specified temperature or within a specified temperature range.

The HUD cooling device 300 may include a movable valve that alternately covers and uncovers the outlet 114. In an example the valve may be attached on one end of the periphery of the outlet opening and slide off of the outlet opening or onto the outlet opening depending on the temperature. The valve may be attached at two or more points or broken into multiple pieces and opened in a swinging-out motion or swinging in motion like doors that open or split in the middle. Many other valve designs and configurations are contemplated that could control the amount and direction of airflow from the HVAC duct 112 towards the heatsink 108.

In FIG. 3, a valve is shown that is a pivoting disk or pivoting flap shape where the valve may include protrusions in the middle of the valve to allow the valve to pivot both open and closed. To illustrate this example valve. FIG. 3 shows the valve in the open position 304 and the valve in the closed position 306. The valve may open and close through rotation movement and may either complete a full rotation to open and close or the valve may reverse its movement direction to alternate between an open and closed position. The amount the valve opens may increase the airflow and accordingly the rate of heat dissipation in the heatsink 108.

In an example, the temperature sensor 302 may detect that a temperature has exceeded a specified temperature or upper bound of a specified temperature range. In response to the detection by the temperature sensor 302, the valve may move to he the valve in the open position 304. In response to a detection by the temperature sensor 302, the valve may move to he the valve in the closed position 306 to decrease airflow when the temperature is detected to he below a specified temperature or lower bound of a specified temperature range. Additionally, the valve may he adjusted incrementally to be fractionally in an open or closed position in response to a detection of temperature by the temperature sensor. For example, the valve may reach an open position based proportionally on where in a temperature range the temperature sensor detects the temperature of the HUD. For example, the bottom of the specified temperature range may correspond to a zero percent valve open position (i.e. a closed position) and the top of the specified temperature range may correspond to a one-hundred percent open valve position. With this example temperature and valve correspondence, each temperature detection can identify a corresponding degree or percentage of valve openness to match how close to measured temperature in the PGU 106 may be to the top of the specified temperature range. In this way, the valve may dynamically respond to produce additional airflow and heat dispersion ability along the heatsink 108 based on a potentially changing temperature measured by the temperature sensor 108.

The valve opening may be controlled by a microprocessor stored in a main board of the HUD 104. A wire for transmitting control signals and motor, such as a servo motor, may connect the HUD 104 and the valve to allow varying movements and control. The temperature sensor 302 may provide the HUD 104 an analog or digital temperature reading that can be processed to determine a valve position.

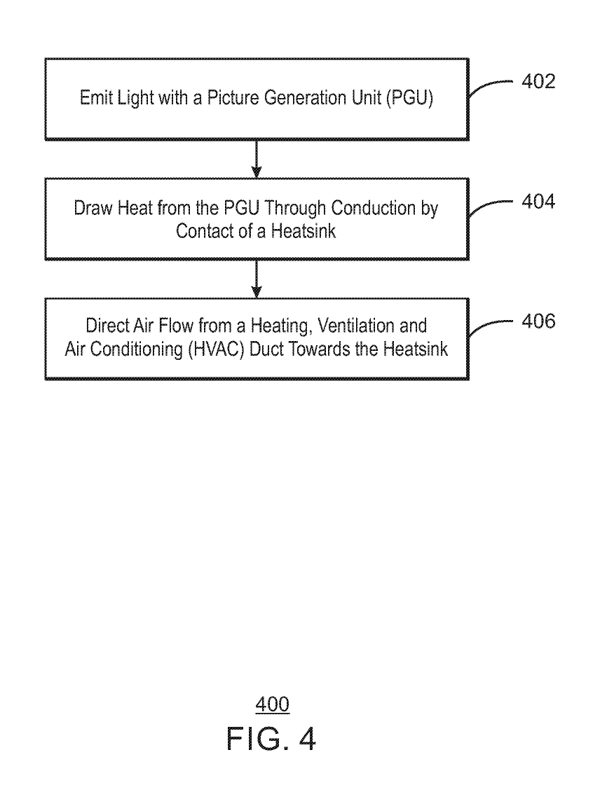

FIG. 4 is a process flow diagram of an example method for cooling a HUD. While the blocks are shown in a specified order, one or more blocks may change in order based on a particular environment of implementation.

At block 402, the PGU emits light with a Picture Generation Unit (PGU) of a HUD module. In an example, the PGU includes light emitting diodes. At block 408, a heatsink to the PGU draws heat from the PGU through conduction by contact with the PGU where the heatsink is attached to the HUD module and dissipates heat through convection. In an example, the heatsink comprises a plurality of fins for heat dissipation that are formed in parallel formation along the heatsink. In an example, the heatsink has a flat surface contacting the PGU and an opposite side of the heatsink shaped to form a plurality of fin shaped protrusions. The heatsink may be attached to the PGU at an orientation that enables airflow directed by the outlet to run between the plurality of fin shaped protrusions of the heatsink. The plurality of fin shaped protrusions may be curved so that airflow directed through the plurality of fin shaped protrusions is directed away from the HUD and the outlet of the HVAC duct.

At block 410, an outlet on a Heating, Ventilation, and Air Conditioning (HVAC) duct directs airflow from the HVAC duct towards the heatsink. The position of the outlet on the HVAC duct may direct airflow to move parallel to the plurality of fins of the heatsink, In an example, the method may further include covering the opening of the outlet of the HVAC duct with a valve, the valve to alternatively allow or disallow airflow from the HVAC duct towards the heatsink. In this example the method may include signaling the valve to open in response to a detection by a temperature sensor of the HUD module of the temperature exceeding a first threshold temperature. Further, the method may include signaling the valve to close in response to a detection by the temperature sensor of the HUD module of the temperature of the HUD module passing below a second threshold temperature. In these examples, the first threshold temperature and the second threshold temperature are the same value. For example in which a temperature sensor is used in the method of cooling, the temperature sensor may be a thermistor located on the PGU or the heatsink. In an example, the HVAC duct is contained within an instrument panel of the vehicle.

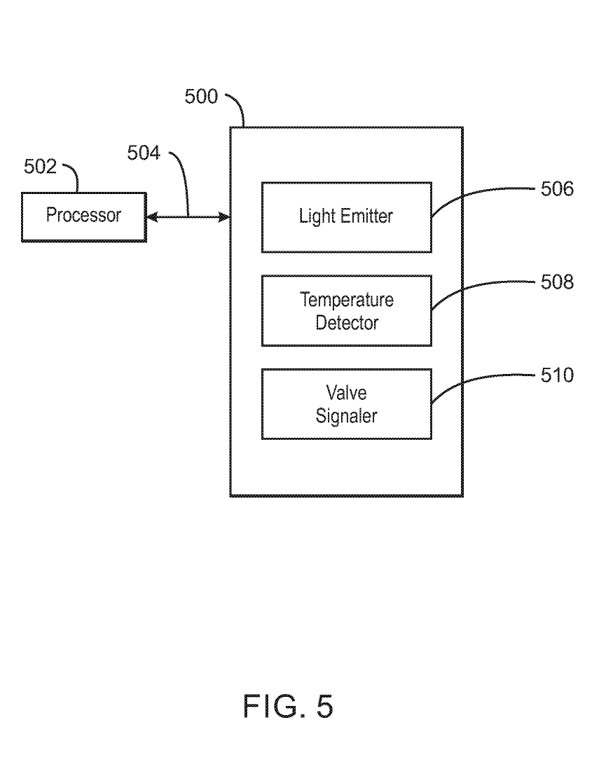

FIG. 5 is a drawing of an example computer-readable medium 500 storing instructions, that when executed on a processor cools a HUD through control of an HVAC outlet valve. The tangible, non-transitory, computer-readable medium 500 includes instructions that, when executed by a processor 502 can direct the processor 502 through a bus 540 to cool a HUD. In an example, the computer-readable medium 500 may be stored on the HUD.

The computer-readable medium 500 includes light emitter 506 to control and signal a display or group of lights to emit light showing particular pictures, patterns, numbers, or symbols. In an example the light emitter may be controlling a PGU with an LCD screen with LED lights backlighting the LCD screen.

The computer-readable medium 500 may be coupled to a temperature detector 508 to detect the temperature of a PGU, HUD, or a heatsink attached to the PGU, HUD, or subcomponents of either the PGU or HUD. The computer-readable medium 500 includes a valve signaler 510 to signal a valve to open in response to the detection of the temperature by the temperature detector 508. The valve may be attached to an HVAC duct. In an example, there may be a number of valves on a single HVAC duct responsive to the temperature detector 508. In an example, there may be a number of valves each on a different HVAC duct that may be responsive to the temperature detector 508.

What is claimed is:

1. A vehicle head up display cooling system, comprising:
a Head Up Display (HUD) module to emit light with a Picture Generation Unit (PGU);
a heatsink attached to the HUD module to draw heat from the PGU through conduction and dissipate heat through convection; and
a Heating, Ventilation, and Air Conditioning (HVAC) duct with an outlet to direct airflow from the HVAC duct towards the heatsink.

2. The system of claim 1, wherein the heatsink comprises a plurality of fins for heat dissipation that are formed in parallel formation along the heatsink.

3. The system of claim 2, wherein the position of the outlet on the HVAC duct points directs airflow to move parallel to the plurality of fins of the heatsink.

4. The system of claim 1, comprising a valve covering the opening of the outlet of the HVAC duct, the valve to selectively allow or disallow airflow from the HVAC duct towards the heatsink.

5. The system of claim 4, comprising a temperature sensor of the HUD module to signal the valve to open in response to a detection of the temperature exceeding a first threshold temperature and close in response to a detection of the temperature of the HUD module passing below a second threshold temperature.

6. The system of claim 5, wherein the first threshold temperature and the second threshold temperature are the same value.

7. The system of claim 5, wherein the temperature sensor is a thermistor located on the PGU.

8. The system of claim 1, wherein the PGU comprises light emitting diodes.

9. The system of claim 1, wherein the heatsink has a flat surface contacting the PGU and an opposite side of the heatsink is shaped to form a plurality of fin shaped protrusions, the heatsink attached to PGU at an orientation so that airflow directed by the outlet runs between the plurality of fin shaped protrusions of the heatsink, the plurality of fin shaped protrusions curving so that airflow directed through the plurality of fin shaped protrusions is directed away from the HUD and the outlet of the HVAC duct.

10. The system of claim 1, wherein the HVAC duct is contained within an instrument panel of the vehicle.

11. A method for cooling a Head Up Display (HUD) in a vehicle, comprising:
emitting light with a Picture Generation Unit (PGU) of a HUD module;
drawing heat from the PGU through conduction by contact of a heatsink to the PGU, where the heatsink is attached to the HUD module and dissipates heat through convection;
and
directing airflow from a Heating, Ventilation, and Air Conditioning (HVAC) duct towards the heatsink, the airflow directed by an outlet on the HVAC duct.

12. The method of claim 11, wherein the heatsirik comprises a plurality of fins for heat dissipation that are formed in parallel formation along the heatsink.

13. The method of claim 12, wherein the position of the outlet on the HVAC duct points directs airflow to move parallel to the plurality of fins of the heatsink.

14. The method of claim 11, comprising covering the opening of the outlet of the HVAC duct with a valve, the valve to selectively allow or disallow airflow from the HVAC duct towards the heatsink.

15. The method of claim 14, comprising:
signaling the valve to open in response to a detection by a temperature sensor of the HUD module of the temperature exceeding a first threshold temperature; and
signaling the valve to close in response to a detection by the temperature sensor of the HUD module of the temperature of the HUD module passing below a second threshold temperature.

16. The method of claim 15, wherein the first threshold temperature and the second. threshold temperature are the same value.

17. The method of claim 15, wherein the temperature sensor is a thermistor located on the PGU.

18. The method of claim 11, wherein the PGU comprises light emitting diodes.

19. The method of claim 11, wherein the heatsink has a flat surface contacting the PGU and an opposite side of the heatsink is shaped to form a plurality of fin shaped protrusions, the heatsink attached to the PGU at an orientation so that airflow directed by the outlet runs between the plurality of fin shaped protrusions of the heatsink, the plurality of fin shaped protrusions curving so that airflow directed through the plurality of fin shaped protrusions is directed away from the HUD and the outlet of the HVAC duct.

20. The method of claim 1, wherein the HVAC duct is contained within an instrument panel of the vehicle.

21. A device Head Up Display (HUD) cooling comprising:
a Head Up Display (HUD) module to emit light with a Picture Generation Unit (PGU);
a heatsink attached to the HUD module to draw heat from the PGU through conduction and dissipate heat through convection; and
a Heating, Ventilation, and Air Conditioning (HVAC) duct with an outlet to direct airflow from the HVAC duct towards the heatsink.

22. The device of claim 21, wherein the heatsink comprises a plurality of fins for heat dissipation that are formed in parallel formation along the heatsink.

23. The device of claim 22, wherein the position of the outlet on the HVAC duct points directs airflow to move parallel to the plurality of fins of the heatsink.

24. The device of claim 21, comprising a valve covering the opening of the outlet of the HVAC duct, the valve to alternatively allow or disallow airflow from the HVAC duct towards the heatsink.

25. The device of claim 24, comprising a temperature sensor of the HUD module to signal the valve to open in response to a detection of the temperature exceeding a first threshold temperature and close in response to a detection of the temperature of the HUD module passing below a second threshold temperature.

26. The device of claim 25, wherein the first threshold temperature and the second threshold temperature are the same value.

27. The device of claim 25, wherein the temperature sensor is a thermistor located on the PGU.

28. The device of claim 21, wherein the PGU comprises light emitting diodes.

29. The device of claim 21, wherein the heatsink has a flat surface contacting the PGU and an opposite side of the heatsink is shaped to form a plurality of fin shaped protrusions, the heatsink attached to the at an orientation so that airflow directed by the outlet runs between the plurality of fin shaped protrusions of the heatsink, the plurality of fin shaped protrusions curving so that airflow directed through the plurality of fin shaped protrusions is directed away from the HUD and the outlet of the HV AC duct.

30. The device of claim 21, wherein the HVAC duct is contained within an instrument panel of the vehicle.
